(19) United States
(12) Patent Application Publication
(10) Pub. No.: US 2002/0188907 A1
(43) Pub. Date: Dec. 12, 2002

(54) Data transfer system

(75) Inventor: Eiji Kobayashi, Minato-ku (JP)

Correspondence Address: SUGHRUE MION, PLLC, 2100 PENNSYLVANIA AVENUE, N.W., WASHINGTON, DC, 20037, US

(73) Assignee: NEC CORPORATION

(21) Appl. No.: 10/136,401

(22) Filed: May 2, 2002

(30) Foreign Application Priority Data
May 30, 2001 (JP) 2001-163279

(51) Int. Cl. H03M 13/00

(52) U.S. Cl. 714/758

(57) ABSTRACT

A device is disclosed that allows a host device that is the source of data transfer to detect whether or not data have been correctly written to a memory device without interfering with the effective data transfer. When the host device issues a request to write sector data, a host adapter deblocks the sector data into data blocks and transfers the data in data block units to a memory adapter. The memory adapter not only memory-writes the data blocks to a memory device, but also generates block CRC code from the data blocks and returns the code as a write reply to the host adapter. The host adapter receives the block CRC code, carries out a CRC operation to reconstruct CRC code of complete sector data, performs a correspondence check with the CRC code of the original sector data, and reports the check results to the host device.

### BACKGROUND OF THE INVENTION

1. Field of the Invention

The present invention relates to a data transfer system, and in particular, to a data transfer system that performs a data check.

2. Description of the Related Art

If a device that is the source of a data transfer and a device that performs a memory write of data to a memory device are in the same LSI (Large-Scale Integrated Circuit), it is possible to detect whether the data has been reliably written, and it is also easy to detect an abnormal state of the device such as altered data.

In a large-scale system such as a large-scale disk array device, however, the data is not necessarily processed in a single LSI, and writing to a target memory device may be realized by way of various types of buses within the system such as PCI (Peripheral Component Interconnect) buses, and system buses as well as the plurality of LSIs that control these buses.

The above-described large scale system of the prior art was of a system configuration that did not allow a data transfer source to completely verify that data had been written correctly to the ultimate memory device, despite the possibility that erroneous data may be recorded in a memory device due to, for example, the alteration of data to invalid data while being transferred due to the occurrence of an abnormality caused by hardware breakdowns during the data transfer, or due to the occurrence of a parity error caused by electrical noise in the bus that is being used.

The most reliable method for enabling the device of a data transfer source to completely verify that correct data has been written to the ultimate memory device involves the performance of a correspondence check (verification) in which the data transfer source device reads from the memory device the data that it has written to determine that the data have been written correctly, but this method has the attendant problems of lowering the effective data transmission rate and reducing performance.

It is an object of the present invention to provide a data transfer system in which, in the device (LSI) that performs final writing to a memory device, the written data are sampled to produce CRC (Cyclic Redundancy Check) code of portions of the data as block CRC code and returns this block CRC code to the data transfer source device; and in the data transfer source device, the CRC code of all of the transferred data are reconstructed the CRC code of the sector data, which is main data to be deblocked to a plurality of blocks, from the returned block CRC code to perform a correspondence check; whereby the data transfer source can guarantee the values of data that are written to a memory device without interfering with the actual data transfer.

As an example of the prior art, Japanese Patent Laid-open No. 15354/95 discloses a “Method For Confirming CRC Code and Device Thereof.” In this prior art, in a transmission device that divides data blocks (corresponding to sector data in the present invention) into sub-block (corresponding to data blocks in the present invention) and then transmits, initial setting values are used to generate partial CRC codes (corresponding to block CRC codes in the present invention) for each received sub-block. The CRC codes are assembled from the partial CRC codes for the entire data block and verification of this data block then performed. This example of the prior art therefore differs conclusively from the present invention with respect to the assembly, on the receiving side, of the CRC codes for the entire data block from the partial CRC codes, the present invention being constituted such that the CRC codes for all sector data are reconstructed from block CRC codes at the data transfer source.

### SUMMARY OF THE INVENTION

In a data transfer system that is provided with a host adapter that deblocks sector data for which a write request has been issued from a host device and that issues a write request as a plurality of data blocks, and a memory adapter that memory-writes to a memory device the data blocks for which the write request has been issued;

the data transfer system of the present invention comprises:

the memory adapter, which, when performing a memory write to the memory device of data blocks for which a write request has been issued from the host adapter, generates a particular determined code from the data blocks and returns this code to the host adapter as a write reply; and

the host adapter, which reconstructs CRC code of all sector data from the particular determined code that has been returned as a write reply from the memory adapter, verifies that the code is the CRC code of the original sector data, and reports the presence or absence of errors to the host device.

In addition, in the data transfer system of the present invention, the particular determined code is block CRC code that is computed for portions of the data blocks in a state that has particular initial values.

Further, when generating the block CRC code in the data transfer system of the present invention, the initial values are zero.

Still further, the data transfer system of the present invention is provided with a crossbar circuit between the host adapter and the memory adapter that repeats the data transfer.

In addition, in a data transfer system that is provided with a host adapter that deblocks sector data for which a write request has been issued from a host device and that issues a write request as a plurality of data blocks, a memory adapter that memory-writes to a memory device data blocks for which a write request has been issued, and a bus that interconnects the host adapter and the memory adapter;

the data transfer system of the present invention comprises:

the memory adapter, which, when performing a memory write to the memory device of data blocks for which a write request has been issued from the host adapter by way of the bus, generates block CRC code for the data blocks and returns this code as a write reply to the host adapter by way of the bus; and

the host adapter, which reconstructs CRC code of all sector data from the block CRC code that has been returned as a write reply from the memory adapter by way of the bus, verifies that the code is the CRC code of the original sector data, and reports the presence or absence of errors to the host device.

In addition, in a data transfer system that is provided with a plurality of host adapters that deblocks sector data for which a write request has been issued from a host device and that issue a write request as a plurality of data blocks, a plurality of memory adapters that memory-write to a plurality of memory devices data blocks for which the write request has been issued, and a bus that interconnects the host adapters and the memory adapters;

the data transfer system of the present invention comprises:

the memory adapters, which, when performing a memory write to a memory device of data blocks for which a write request has been issued from one of the host adapters by way of the bus, generates block CRC code for the data blocks and returns this code as a write reply to said host adapter by way of said bus; and

the host adapter, which reconstructs CRC code of all sector data from the block CRC code that has been returned as a write reply from the memory adapter by way of the bus, verifies that the code is the CRC code of the original sector data, and reports the presence or absence of errors to the host device.

Still further, the host adapter in the data transfer system of the present invention includes: a data buffer for buffering the sector data; block CRC code to CRC code conversion circuit for reconstructing CRC code of all sector data from block CRC code that has been returned as the write reply; and a CRC code check circuit for verifying that the CRC code that has been reconstructed by the block CRC code to CRC code conversion circuit is the CRC code of the original sector data.

In addition, in the data transfer system of the present invention, a plurality of the CRC code check circuits are provided in correspondence with channels, the channel of a data transfer source is specified by a channel number, and verification of reconstructed CRC code is realized using the CRC code check circuit that corresponds to that channel.

Furthermore, the memory adapter in the data transfer system of the present invention includes: a data buffer for buffering data blocks for which a write request has been issued from the host adapter; and a block CRC code generation circuit that generates block CRC code for data blocks that have been memory-written from the data buffer to the memory device.

Still further, the block CRC code generation circuit in the data transfer system of the present invention sets initial values to zero when generating the block CRC code.

In a data transfer system that is provided with: a host adapter that deblocks sector data for which a write request has been issued from a host device and that issues a write request as a plurality of data blocks; a memory adapter that memory-writes to a memory device data blocks for which the write request has been issued; and a crossbar circuit that interconnects the host adapter and the memory adapter;

the data transfer system of the present invention comprises:

the memory adapter, which, when performing a memory write to the memory device of data blocks for which a write request has been issued from the host adapter by way of the crossbar circuit, generates block CRC code from the data blocks and returns this code as a write reply to the host adapter by way of the crossbar circuit; and

the host adapter, which reconstructs CRC code of all sector data from the block CRC code that has been returned as a write reply from the memory adapter by way of the crossbar circuit, verifies that the code is the CRC code of the original sector data, and reports the presence or absence of errors to the host device.

The host adapter in the data transfer system of the present invention includes: a data buffer for buffering the sector data; a block CRC code to CRC code conversion circuit for reconstructing the CRC code of all sector data from the block CRC code that has been returned as the write reply from the memory adapter; a CRC code check circuit for verifying that the CRC code that has been reconstructed by the block CRC code to CRC code conversion circuit is the CRC code of the original sector data; a host control circuit for controlling the host device; and a bus interface for controlling the interface with the crossbar circuit.

Still further, in the data transfer system of the present invention, a plurality of the CRC code check circuits are provided in correspondence with channels, the channel of a data transfer source is specified by a channel number, and verification of reconstructed CRC code is realized using the CRC code check circuit that corresponds to that channel.

Furthermore, the memory adapter in the data transfer system of the present invention includes: a data buffer for buffering data blocks for which a write request has been issued from the host adapter; a block CRC code generation circuit for generating block CRC code for data blocks that have been memory-written to the memory device from the data buffer; and a bus interface for controlling the interface with the crossbar circuit.

Further, in the data transfer system of the present invention, the block CRC code generation circuit sets initial values to zero when generating the block CRC code.

Still further, in the data transfer system of the present invention, the crossbar circuit includes: a first bus interface for controlling the interface with the host adapter; a second bus interface for controlling the interface with the memory adapter; and a plurality of data buffers provided between the first bus interface and the second bus interface.

In the data transfer system of the present invention, when a host device issues to a memory device a write request for a particular collection of data (hereinbelow referred to as “sector data”), the host adapter deblocks the sector data into data (hereinbelow referred to as “data blocks”) for every particular fixed number of bytes and transfers the data blocks to the memory adapter in data block units. The memory adapter both memory-writes the data blocks to a memory device and generates CRC code (hereinbelow referred to as “block CRC code”) from the data blocks, and returns the block CRC code to the host adapter as a write reply to the write request. Upon receiving the block CRC code as the write reply, the host adapter performs a CRC operation on the block CRC code, reconstructs the CRC code of all sector data, performs a correspondence check with the CRC code of the original sector data, and reports the check results to the host device. In this way, the host device that is the data transfer source can detect whether or not sector data for which a write request has been issued have been normally written to a memory device.

The above and other objects, features, and advantages of the present invention will become apparent from the following description with reference to the accompanying drawings, which illustrate examples of the present invention.

### BRIEF DESCRIPTION OF THE DRAWINGS

FIG. 1 is a circuit block diagram showing the configuration of the data transfer system according to the first embodiment of the present invention.

FIG. 2 is a flow chart showing the processing of the data transfer system according to the first embodiment.

FIG. 3 is a circuit block diagram showing the configuration of the data transfer system according to the second embodiment of the present invention.

FIG. 4 is a circuit block diagram showing the configuration of the data transfer system according to the third embodiment of the present invention.

FIG. 5 shows an example of the constitution of transfer data between the host device and the host adapter.

FIG. 6 shows an example of the constitution of transfer data between the host adapter and the memory adapter.

FIG. 7 shows an example of the constitution of transfer data between the host adapter and the memory device.

FIG. 8 shows an example of the constitution of transfer data between the memory adapter and the host adapter.

FIG. 9 is a view for explaining the principles of operation of the data transfer system of this embodiment.

FIG. 10 is a circuit block diagram showing the unit composition of a normal CRC arithmetic circuit and the unit composition of the CRC arithmetic circuit following conversion of the computation sequence.

FIG. 11 is a circuit block diagram showing an example of the unit composition of a CRC arithmetic circuit that is used in the present embodiment.

FIG. 12 is a circuit block diagram showing an example of the overall configuration of the CRC arithmetic circuit that is used in the present embodiment.

### DETAILED DESCRIPTION OF THE PREFERRED EMBODIMENTS

Explanation next regards the details of embodiments of the present invention with reference to the accompanying drawings.

### FIRST EMBODIMENT

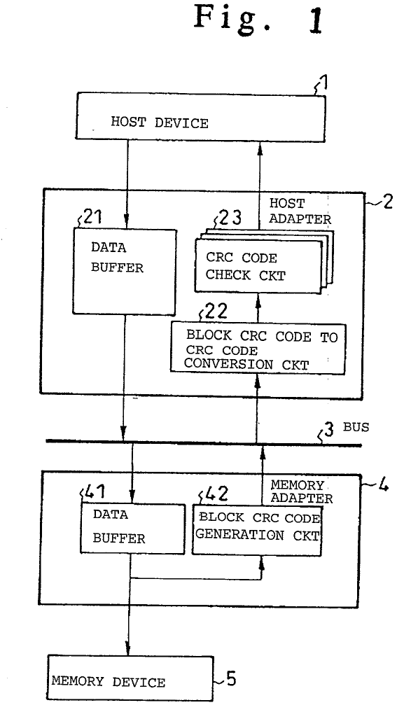

We refer first to FIG. 1, which is a circuit block diagram showing the configuration of the data transfer system according to the first embodiment of the present invention. The principal components of the data transfer system according to this embodiment are constituted by: host device 1 that issues a request to write sector data; host adapter 2 that deblocks the sector data for which a write request has been issued from host device 1 into data block units and that issues a write request to memory adapter 4; system bus 3 that connects host adapter 2 and memory adapter 4; memory adapter 4 that takes in data blocks for which a write request has been issued from host adapter 2, memory-writes the data blocks to memory device 5, generates block CRC code from the data blocks, and returns the block CRC code to host adapter 2 as a write reply; and memory device 5 for memory-writing the data blocks.

FIG. 1 presents a simplified view of the arrangement in the data transfer between host device 1 and memory device 5, and in the present invention, a limit is not set on the number of connections performed by the host devices 1 and memory devices 5.

Host adapter 2 is constituted to include: data buffer 21 for receiving the sector data for which a write request has been issued from host device 1; block CRC code to CRC code conversion circuit 22 for reconstructing the block CRC code that is returned as a write reply from memory adapter 4 to the CRC code of all sector data; and a plurality of CRC code check circuits 23 for verifying, for each channel, the correctness of the CRC code that has been reconstructed by the block CRC code to CRC code conversion circuit 22. The results of the CRC code check that are reported to host device 1 from host adapter 2 are reported by way of an interrupt signal line (not shown in the figure).

Memory adapter 4 is constituted to include: data buffer 41 for holding data blocks for which a write request has been issued from host adapter 2; and block CRC code generation circuit 42 for taking in data blocks that have been memory-written to memory device 5, generating block CRC code, and returning the block CRC code to host adapter 2 as a write reply.

The data transfer system according to the first embodiment is an example in which, for example, the sector data transferred from host device 1 to memory device 5 through a path within a disk array device, so other circuits such as some hard disks are actually necessary, but in this case, these components have been omitted here.

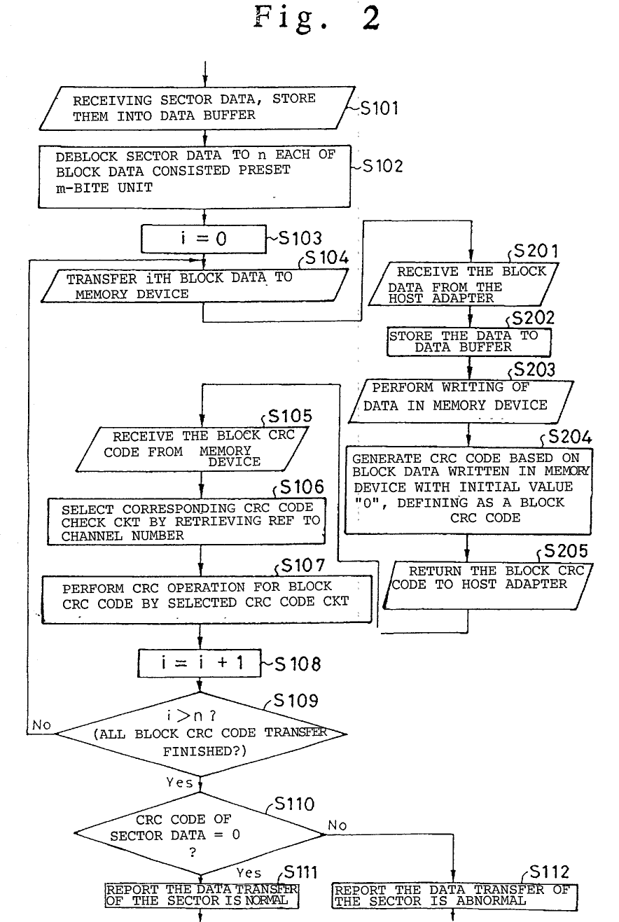

Referring now to FIG. 2, the processing of host adapter 2 is constituted by: step S101 for receiving sector data, step S102 for deblocking to data blocks, step S103 for initializing the counter, step S104 for transferring data blocks, step S105 for receiving block CRC code, step S106 for selecting the CRC code check circuit, step S107 for CRC operation, step S108 for incrementing the counter, step S109 for determining completion of data transfer, step S110 for determining whether CRC code=0, step S111 for reporting normal transfer, and step S112 for reporting abnormal transfer.

Referring to FIG. 2, the processing of memory adapter 4 is similarly made up by: step S201 for receiving data blocks, step S202 for storing in data buffers, step S203 for executing memory write, step S204 for generating block CRC code, and step S205 for returning the block CRC code.

In FIG. 2, the processing of host adapter 2 and the processing of memory adapter 4 are shown as a series of sequential flow charts to facilitate understanding, but the pipeline operation of host adapter 2 and memory adapter 4 can naturally operate independently as parallel sequences.

Explanation next regards the operation of the data transfer system according to the first embodiment that is configured as described above.

When a write request for sector data is issued from host device 1, host adapter 2 takes in the sector data from host device 1 and stores the sector data in data buffer 21 (Step S101).

Host adapter 2 next deblocks the sector data that have been stored in data buffer 21 into n blocks having a prescribed number of m bytes each(Step S102).

After initializing counter to 0 (Step S103), host adapter 2 then transfers the data blocks of block number i to memory adapter 4 (Step S104). At this time, a block number and a channel number that are unique within the system are embedded in the header for each transferred data block and then the write request is issued.

Upon receiving the data blocks from host adapter 2 by way of system bus 3 (Step S201), memory adapter 4 stores the received transfer data in data buffer 41 (Step S202).

Memory adapter 4 next memory-writes the data blocks that have been stored in data buffer 41 to memory device 5 that is arranged to be under control of memory adapter 4.

Simultaneous with the memory-write of the data blocks, memory adapter 4 transfers the data blocks as is to block CRC code generation circuit 42, and block CRC code generation circuit 42 generates CRC code in which initial values are set to zero as block CRC code (Step S204). Details regarding an actual example of the generation of block CRC code by block CRC code generation circuit 42 are next described in embodiment 1 below.

Memory adapter 4 next returns the generated block CRC code by way of system bus 3 to host adapter 2 as a write reply (Step S205).

Upon receiving the block CRC code that has been returned as a write reply from memory adapter 4 (Step S105), host adapter 2 uses the block CRC code to CRC code conversion circuit 22 to specify the channel of the data transfer source and select the corresponding CRC code check circuit 23 (Step S106), and then uses the selected CRC code check circuit 23 to perform a CRC computation of the block CRC code that has been returned as a write reply (Step S107). An actual example of the CRC computation by means of the block CRC code to CRC code conversion circuit 22 is described in embodiment 1 below.

Host adapter 2 next increments counter i by one (Step S108); determines whether or not i>n, i.e., whether or not the transfer of all data blocks has been completed (Step S109); and if not completed, returns the control to Step S104 to transfer the next data block to memory device 5.

If, on the other hand, i is not greater than n (“Yes” in Step S109), the transfer of all data blocks has been completed; and host adapter 2 then determines whether or not the CRC codes of all sector data that have then been generated are all 0 (Step S110); and if all 0 , reports to host device 1 that the sector data have been transferred normally (Step S111). If the CRC codes for all sector data are not all 0 , host adapter 2 reports abnormal transfer to host device 1 as a CRC error (Step S112).

Thus, according to the first embodiment, host device 1, which is the data transfer source, is able to detect whether sector data have been normally transferred to the ultimate memory device 5, and as a result, the alteration of data at some point along the path of data transfer can be reliably detected and the integrity of data can be increased.

In addition, because this data transfer system does not require that CRC codes always be added to data block units and transferred, the system can be adopted without causing any decrease in the transfer rate of system bus 3.

Further, because this data transfer system is equivalent to a data transfer system of the prior art with the exception of the path by which block CRC codes are returned as a write reply, the system of the present invention can be easily adopted to raise the integrity of data without requiring drastic alteration of circuits.

Still further, since the block CRC code to CRC code conversion circuit 22 and CRC code check circuit 23 are located at host adapter 2, a configuration that includes a plurality of host devices 1 does not result in an increase in hardware on the memory adapter 4 side, and circuit complexity can be prevented.

In addition, the system is of a configuration that requires no more than one block CRC code generation circuit 42 in memory adapter 4, which controls memory device 5. As a result, the circuit scale and construction of memory adapter 4 need not be altered even when host device 1 performs a multiplex channel data transfer and a plurality of host devices 1 and host adapters silicon substrate are present, and the circuit scale of memory adapter 4 can therefore be decreased.

### SECOND EMBODIMENT

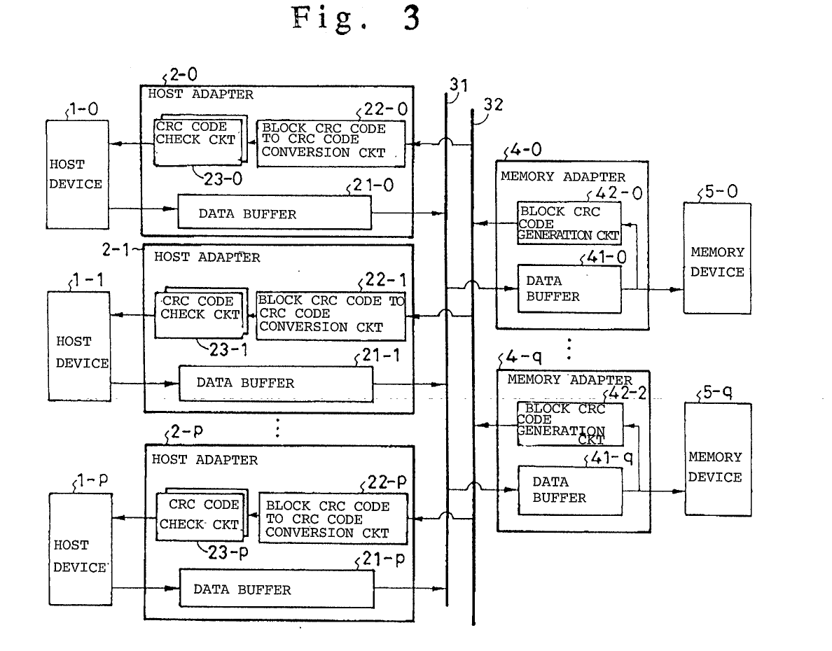

We now refer to FIG. 3, in which is shown a circuit block diagram of the configuration of the data transfer system according to the second embodiment of the present invention. The principal components of the data transfer system of this embodiment are constituted by: host devices 1-0-1-p; host adapters 2-0-2-p; request bus 31; reply bus 32; memory adapters 4-0-4-q; and memory devices 5-0-5-q.

Host adapters 2-0-2-p are constituted to include: data buffers 21-0-21-p, block CRC code to CRC code conversion circuits 22-0-22-p; and CRC code check circuits 23-0-23-p.

Memory adapters 4-0-4-p are constituted to include: data buffers 41-0-41-q and block CRC code generation circuits 42-0-42-q.

The operation of the data transfer system according to the second embodiment that is constructed according to the foregoing description is substantially the same as the data transfer system according to the first embodiment shown in FIG. 1, and despite the plurality of memory devices 5-0-5-q, the circuits for verifying the correctness of data transfers are in host adapters 2-0-2-p, which are the sources of data transfer, and data can therefore be spread between memory devices 5-0-5-q and transferred.

### THIRD EMBODIMENT

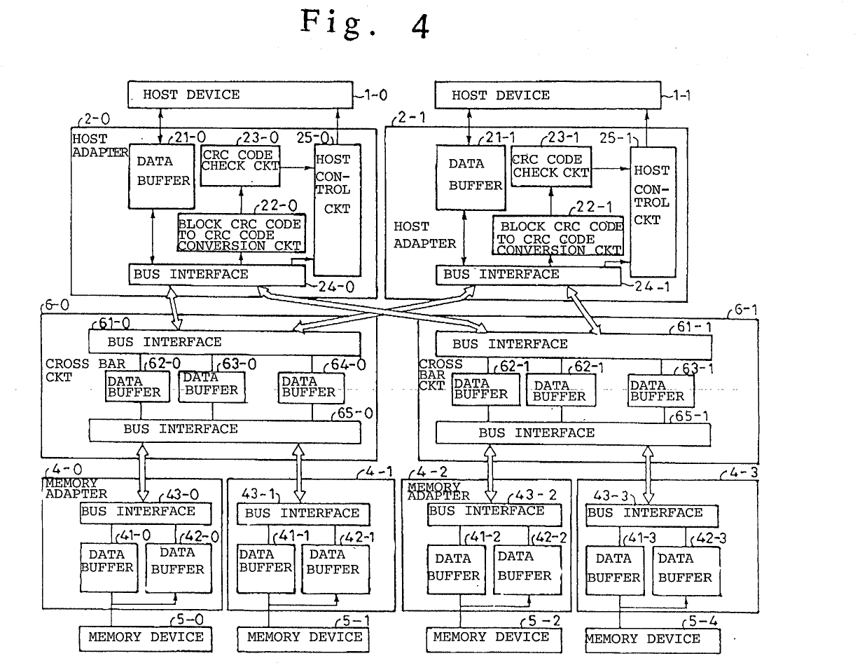

We now refer to FIG. 4, in which is shown a circuit block diagram of the configuration of the data transfer system according to the third embodiment of the present invention.

The data transfer system according to this embodiment includes crossbar circuit 6 connected as a device for repeating in communication between host device 1 and memory device 5. To state in greater detail, the principal components of the data transfer system according to this embodiment are constituted by: host devices 1-0 and 1-1; host adapters 2-0 and 2-1; crossbar circuits 6-0 and 6-1; memory adapters 4-0-4-3; and memory devices 5-0-5-3.

Host adapters 2-0 and 2-1 are constituted to include: data buffers 21-0 and 21-1; the block CRC code to CRC code conversion circuits 22-0 and 22-1; CRC code check circuits 23-0 and 23-1; bus interfaces 24-0 and 24-1; and host control circuits 25-0 and 25-1, respectively.

Crossbar circuits 6-0 and 6-1 are constituted to include: bus interfaces 61-0 and 61-1; data, buffers 62-0-64-0 and 62-1-64-1, and bus interfaces 65-0 and 65-1, respectively.

Memory adapters 4-0-4-3 are constituted to include: data buffers 41-0-41-3; block CRC code generation circuits 42-0-42-3; and bus interfaces 43-0-43-3, respectively.

The data transfer system according to the third embodiment is configured to allow any host device 1 to access all memory devices 5, and the configurations of host adapters 2 and memory adapters 4 do not differ greatly from the configurations in the data transfer systems according to the first and second embodiments that are shown in FIG. 1 and FIG. 3 with the exception of the provision of bus interfaces 24 and bus interfaces 43.

In the data transfer system according to the third embodiment that is constituted as described above, although host adapters 2 spread and store data blocks among memory devices 5, the correspondence check of CRC code is carried out in CRC code check circuits 23 in host adapter 2 that is the data transfer source, and the data blocks can therefore be spread among memory devices 5 and retained, with the effect that high-speed data transfer can be performed by means of the striping operation of memory devices 5.

On the other hand, not only is the correspondence check of the CRC codes carried out at all host adapters 2, but data blocks are used that have been memory-written to memory devices 5, whereby the advantage is obtained that data can be promptly checked in the event of alteration of data due to hardware breakdown or operation noise even if the hardware for repeating data transfer such as crossbar circuit 6 lacks the capability to check data.

Next, as an actual embodiment that is based on the data transfer system according to the first embodiment shown in FIG. 1, a concrete and detailed explanation is next presented for embodiment-1 regarding the generation of block CRC code by block CRC code generation circuit 42 and the reconstruction of CRC codes by the block CRC code to CRC code conversion circuits 22.

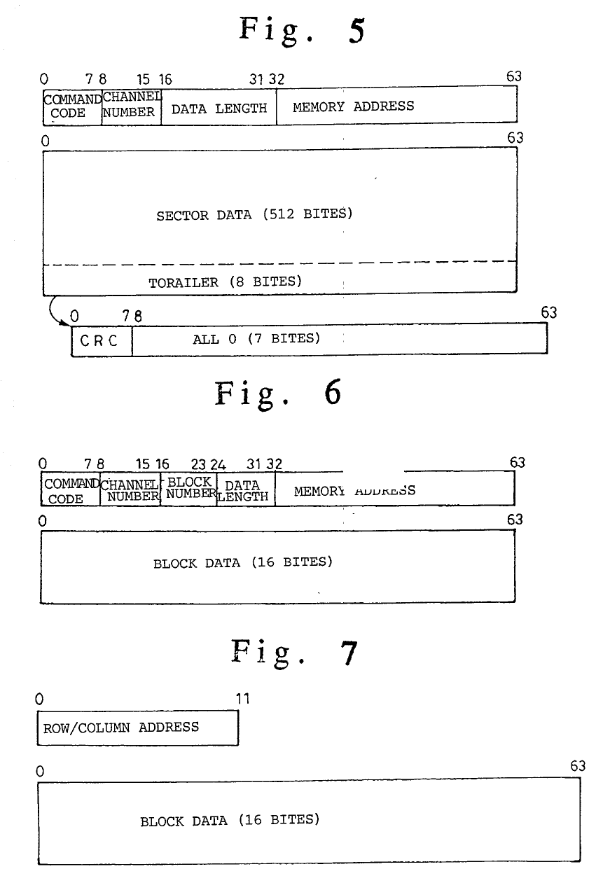

Referring now to FIG. 5, the data that are transferred from host device 1 to host adapter 2 are constituted by an 8-byte header that includes: command code indicating a transfer command that accords with the protocol of system bus 3, a channel number indicating the type of channel used in the transfer, data length indicating the length of the sector data, and a memory address; and 512 bytes of sector data that include an 8-byte trailer. The trailer is made up by one byte of CRC code and seven bytes that are all zero. When transferring sector data, host device 1 must perform a variety of data transfers such as the channel for transferring sector data, the channel for transferring directory information and file names of the sector data, and the channel for generating parity that is unique to RAID (Redundant Arrays of Inexpensive Disks). These transfers are designated by host device 1 that defines the address space in advance, and the channel numbers are embedded as a portion of the header.

Referring now to FIG. 6, data that are transferred from host adapter 2 to memory adapter 4 are made up by: an eight-byte header that includes: command code indicating transfer commands that accords with the protocol of system bus 3, a channel number indicating the type of channel used in the transfer, a block number indicating the number of data blocks that are being transferred, data length indicating the length of the data blocks, and the memory address; and 16-byte data blocks. For data blocks that are partitioned into 16-byte units as the data length that is transferred on a channel, the block number is set such that the initial value is 0 when the data transfer begins and then incremented by +1 with each 16-byte unit.

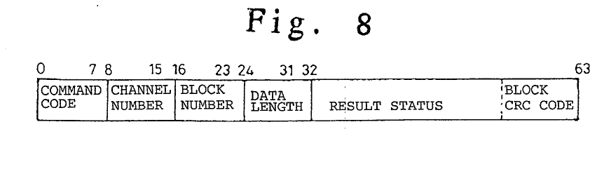

Referring now to FIG. 7, a data block that is memory-written from memory adapter 4 to memory device 5 is constituted by a 12-bit header, which is a ROW/COLUMN address, and a 16-byte data block.

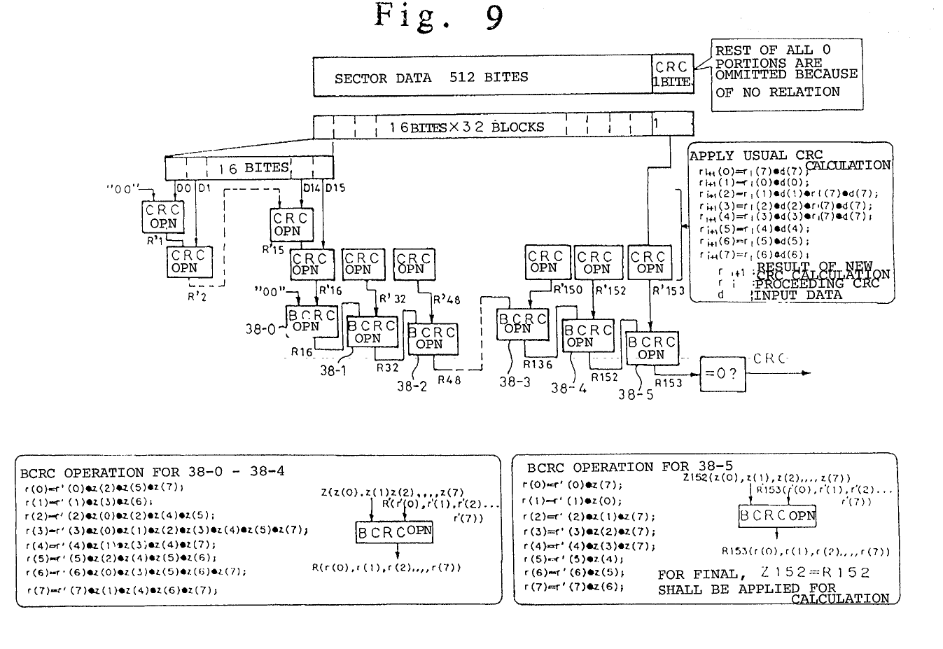

Referring to FIG. 8, the eight-byte write reply that is returned from memory adapter 4 to host adapter 2 is constituted by: a command code indicating a transfer command that accords with the protocol of system bus 3, a channel number indicating the type of channel used in the transfer, a block number indicating the number of the data block that is being transferred, data length indicating the length of the data blocks, and result status, which is status information of the transfer results. In addition, one byte of block CRC code is stored at the tail end of the result status.

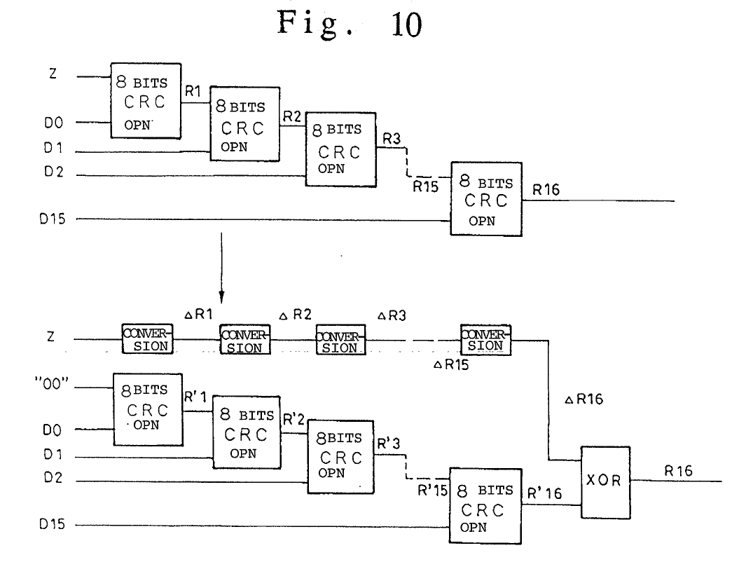

FIG. 9 shows the principles of operation of the data transfer system of this embodiment.

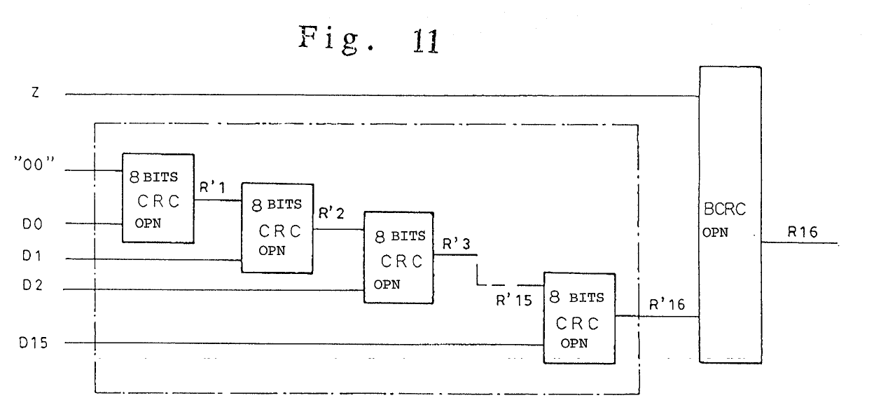

FIG. 10 is a circuit block diagram showing the normal unit structure of a CRC arithmetic circuit and an example of the unit structure of a CRC arithmetic circuit following a change in the computation sequence.

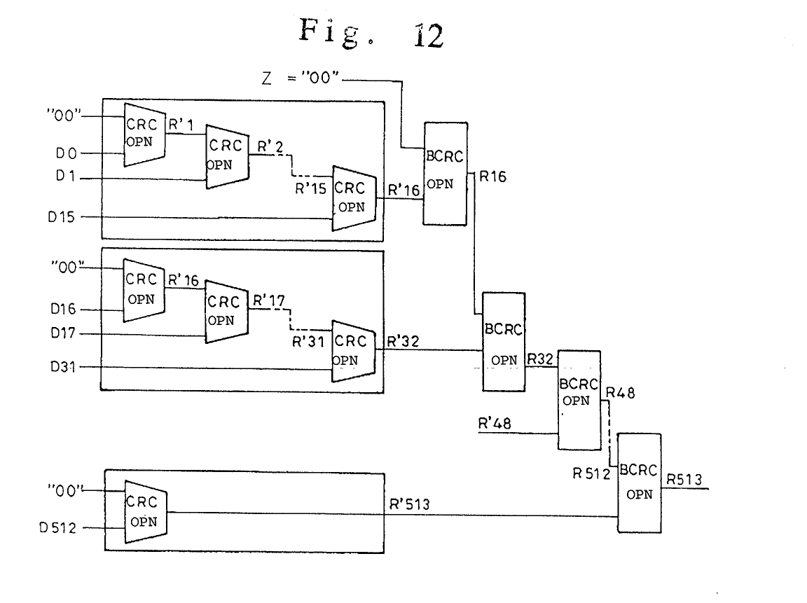

FIG. 11 is a circuit block diagram showing an example of the unit structure of a CRC arithmetic circuit that is used in the present embodiment.

FIG. 12 is a circuit block diagram showing an example of the overall structure of a CRC arithmetic circuit that is used in the present embodiment.

Since CRC code is represented by one byte (8 bits), if primitive polynomial G(x)=x⁸+x⁵+x⁴+x³+1 on finite field GF(2⁸) is considered (Refer to: Imai Hideki, Electronics Essentials, No. 20: “The Essentials of Error Correcting Coding Techniques,” Nihon Kogyo Gijutsu Center, p.164-p.169), an arbitrary number on finite field GF(2⁸) is represented by, for example, an eight-bit vector such as shown in the following equation, where α is the root (primitive element). In addition, the full-sized upper-case letters shown below indicate vectors and matrices, and the half-sized lower-case letters indicate the elements of vectors and matrices.

$$\begin{matrix}0 = [ 0 , 0 , 0 , 0 , 0 , 0 , 0 , 0 ] & \\ 1 = [ 1 , 0 , 0 , 0 , 0 , 0 , 0 , 0 ] & \\ α = [ 0 , 1 , 0 , 0 , 0 , 0 , 0 , 0 ] & \\ {α}^{2} = [ 0 , 0 , 1 , 0 , 0 , 0 , 0 , 0 ] & \\ {α}^{3} = [ 0 , 0 , 0 , 1 , 0 , 0 , 0 , 0 ] & \\ {α}^{4} = [ 0 , 0 , 0 , 0 , 1 , 0 , 0 , 0 ] & \\ {α}^{5} = [ 0 , 0 , 0 , 0 , 0 , 1 , 0 , 0 ] & \\ {α}^{6} = [ 0 , 0 , 0 , 0 , 0 , 0 , 1 , 0 ] & \\ {α}^{7} = [ 0 , 0 , 0 , 0 , 0 , 0 , 0 , 1 ] & \\ {α}^{8} = [ 1 , 0 , 0 , 1 , 1 , 1 , 0 , 0 ] & ( = {α}^{5} + {α}^{4} + {α}^{3} + 1 ) \\ {α}^{9} = [ 0 , 1 , 0 , 0 , 1 , 1 , 1 , 0 ] & ( = {α}^{6} + {α}^{5} + {α}^{4} + α ) \\ ⋮ & \\ {α}^{254} = [ 0 , 0 , 1 , 1 , 1 , 0 , 0 , 1 ] & ( = {α}^{7} + {α}^{4} + {α}^{3} + {α}^{2} ) \\ {α}^{255} = [ 1 , 0 , 0 , 0 , 0 , 0 , 0 , 0 ] & ( = 1 )\end{matrix}$$

The operations for these numbers on finite field GF(2⁸) that are represented by these vectors are realized by vector operations by an 8×8 matrix. To obtain a cyclic code that takes primitive polynomial G(x) as a generator, association matrix T resulting from primitive polynomial G(x) may be used as a transformation matrix.

$$T = [ \begin{matrix}00000001 \\ 10000000 \\ 01000000 \\ 00100001 \\ 00010001 \\ 00001001 \\ 00000100 \\ 00000010\end{matrix} ] \qquad [ Equation 1 ]$$

The generation of CRC codes using association matrix T is carried out as described below.

R(r(0) . . . r(7)) is the vector representation of the register that stores CRC codes, and R1(ri(0) . . . ri(7)) is the value of the CRC codes when the ith item of data Di(di(0) . . . di(7) is read.

R0(r0(0) . . . r0(7))=TD0(d0(0) . . . d0(7))

Ri+1=T {Ri (ri(0) . . . ri(7))+Di (di(0) . . . di(7))}

Calculating Ri+1 row by row results in Formula 1.

### Formula 1

ri+1(0)=ri(7)+di(7)

ri+1(1)=ri(0)+di(0)

ri+1(2)=ri(1)+di(1)+ri(7)+di(7)

ri+1(3)=ri(1)+di(1)+ri(7)+di(7)

ri+1(3)=ri(2)+di(2)+ri(7)+di(7)

ri+1(4)=ri(3)+di(3)+ri(7)+di(7)

ri+1(5)=ri(4)+di(4)

ri+1(6)=ri(5)+di(5)

ri+1(7)=ri(6)+di(6)

However, because this is addition on finite field GF(2⁸), the actual logical operation is an exclusive OR operation resulting in Formula 2. In the following formula, @ is an operator that indicates an exclusive OR operation.

### Formula 2

ri+1(0)=ri(7)@di(7)

ri+1(1)=ri(0)@di(0)

ri+1(2)=ri(1)@di(1)@ri(7)@di(7)

ri+1(3)=ri(2)@di(2)@ri(7)@di(7)

ri+1(4)=ri(3)@di(3)@ri(7)@di(7)

ri+1(5)=ri(4)@di(4)

ri+1(6)=ri(5)@di(5)

ri+1(7)=ri(6)@di(6)

Formula 2 is the CRC operation result when Ri(ri(0) . . . ri(7)) reaches the current step, and an operation of this result and data Di(di(0) . . . di(7)) by association matrix T finds the CRC code of the next step, which is the operation result.

The calculation method in Formula 2 involves generating the one-byte CRC code R1(r1(0) . . . r1(7)) from the two-byte data string of R0(r0(0) . . . r0 (7)) and D0(d0(0) . . . d(7)), but finding R16(r16(0) . . . r16(7)), which generates a 16-byte portion data string, determines the block CRC codes when one data block is 16 bytes. In this regard, only “i” in Formula 2 changes, and Formula 3 can be found.

### Formula 3

r16(0)=r15(7)@d15(7)

r16(1)=r15(0)@d15(0)

r16(2)=r15(1)@d15(1)@r15(7)@d15(7)

r16(3)=r15(2)@d15(2)@r15(7)@d15(7)

r16(4)=r15(3)@d15(3)@r15(7)@d15(7)

r16(5)=r15(4)@d15(4)

r16(6)=r15(5)@d15(5)

r16(7)=r15(6)@d15(6)

Similarly, Formula 4 is resulted as R15(r15(0) . . . r15(7)), and this is developed to between from R14(r14(0) . . . r14(7)) to R2(r2(0) . . . r2(7)).

### Formula 4

r15(0)=r14(7)@d14(7)

r15(1)=r14(0)@d14(0)

r15(2)=r14(1)@d14(1)@r14(7)@d14(7)

r15(3)=r14(2)@d14(2)@r14(7)@d14(7)

r15(4)=r14(3)@d14(3)@r14(7)@d14(7)

r15(5)=r14(4)@d14(4)

r15(6)=r14(5)@d14(5)

r15(7)=r14(6)@d14(6)

As for the formula for calculating R1(r1(0) . . . r1(7)) that is originally calculated first, although the preceding operation result exists as R0(r0(0) . . . r0(7)), it can here be represented as Formula 5 if redefined as initial value Z(z(0) . . . z (7)) for R0(r0(0) . . . r0(7)). Regarding R16(r16(0) . . . r16(7)), which is 16 bytes of block CRC code, the formula is calculated based on data D0(d0(0) . . . d0(7)) to D15(d15(0) . . . d15(7)) and the initial value Z(z(0) . . . z(7)) at the time of this calculation.

### Formula 5

r1(0)=z(7)@d0(7)

r1(1)=z(0)@d0(0)

r1(2)=z(1)@d0(1)@z(7)@d0(7)

r1(3)=z(2)@d0(2)@z(7)@d0(7)

r1(4)=z(3)@d0(3)@z(7)@d0(7)

r1(5)=z(4)@d0(4)

r1(6)=z(5)@d0(5)

r1(7)=z(6)@d0(6)

At this time, the block CRC codes R16(r16(0) . . . r16(7)) that were found for Formula 3 are used to find the CRC operation results that are carried out on D0(d0(0)) . . . d0(7)) to D15(d15(0) . . . d15(7)) when the initial value is Z(z(0) . . . z(7)).

Accordingly, the condition is set that the data that are transferred are the same, and both R16(r16(0) . . . r16(7)) having the operation result that initial values are Z(z(0) . . . z(7)) and R′16(r′16(0) . . . r′16(7)) having the operation result that the initial values are “00” are found; and if the difference between R′16(r′16(0) . . . r′16(7)) and R16(r16(0) . . . r16(7)) can be defined as Δ R16(Δr16(0) . . . Δr16(7)), R16(r16(0) . . . r16(7)) can be generated from R′16(r′16(0) . . . r′16(7)) and ΔR16(Δr16(0) . . . Δr16(7)).

R′16(r′16(0) . . . r′16(7)) is found by Formula 6 based on the fact that the initial value is “00” in Formula 3.

### Formula 6

r′16(0)=r′15(7)@d15(7)

r′16(1)=r′15(0)@d15(0)

r′16(2)=r′15(1)@d15(1)@r′15(7)@d15(7)

r′16(3)=r′15(2)@d15(2)@r′15(7)@d15(7)

r′16(4)=r′15(3)@d15(3)@r′15(7)@d15(7)

r′16(5)=r′15(4)@d15(4)

r′16(6)=r′15(5)@d15(5)

r′16(7)=r′15(6)@d15(6)

Similarly, Formula 7 is resulted from R′15(r′15(0) . . . r′15(7)) and is developed to the formula between from R′14(r′14(0) . . . r′14(7)) to R′2(r′2(0) . . . r′2(7)).

### Formula 7

r′15(0)=r′14(7)@d14(7)

r′15(1)=r′14(0)@d14(0)

r′15(2)=r′14(1)@d14(1)@r′14(7)@d14(7)

r′15(3)=r′14(2)@d14(2)@r′14(7)@d14(7)

r′15(4)=r′14(3)@d14(3)@r′14(7)@d14(7)

r′15(5)=r′14(4)@d14(4)

r′15(6)=r′14(5)@d14(5)

r′15(7)=r′14(6)@d14(6)

Regarding the formula R′1(r′(0) . . . r′1(7)) which is calculated at first substantively, R0(r1(0) . . . r1(7)) exists as the preceding operation results, although the initial value “00” is inserted to R0(r1(0) . . . r1(7)) to produce Formula 8.

### Formula 8

r′1(0)=d0(7)

r′1(1)=d0(0)

r′1(2)=d0(1)@d0(7)

r′1(3)=d0(2)@d0(7)

r′1(4)=d0(3)@d0(7)

r′1(5)=d0(4)

r′1(6)=d0(5)

r′1(7)=d0(6)

R16(r16(0) . . . r16(7)) is defined to equal R16(r16(0) . . . r16(7))@R′16(r′16(0) . . . r′16(7)), and when the difference ΔR16(Δr16(0) . . . Δr16(7)) between R16(r16(0) . . . r16(7)) and R′16(r′16(0) . . . r′16(7)) is found, the formula ΔR16(Δr16(0) . . . Δr16(7)=R16(r16(0) . . . r16(7))@R′16(r′16(0) . . . r′16(7)) is used.

At this time, however, data Di(di(0) . . . di(7)) transfers the same data, and only the difference between R16(r16(0) . . . r16(7)), which is Formula 3, and R′16(r′16(0) . . . r′16(7)), which is Formula 4, is the difference between R1(r1(0) . . . r1(7)) and R′1(r′1(0) . . . r′1(7)).

(1) The Calculation of ΔR1(Δr1(0) . . . Δr1(7))

Accordingly, Formula 9 is found for ΔR1(Δr1(0) . . . Δr1(7)) at the step of transferring the first data.

### Formula 9

Δr1(0)=r1(0)@r′1(0)={d(7)@z(7)}@{d(7)}=z(7)

Δr1(1)=r1(1)@r′1(1)={d(0)@z(0)}@{d(0)}=z(0)

Δr1(2)=r1(2)@r′1(2)={d(1)@z(1)}@{d(1)@d(7)@z(7)}@{d(1)@d(7)}=z(1)@z(7)

Δr1(3)=r1(3)@r′1(3)={d(2)@z(2)}@{d(2)@d(7)@z(7)}@{d(2)@d(7)}=z(2)@z(7)

Δr1(4)=r1(4)@r′1(4)={d(3)@z(3)}@{d(3)@d(7)@z(7)}@{d(3)@d(7)}=z(3)@z(7)

Δr1(5)=r1(5)@r′1(5)={d(4)@z(4)}@{d(4)}=z(4)

Δr1(6)=r1(6)@r′1(6)={d(5)@z(5)}@{d(5)}=z(5)

Δr1(7)=r1(7)@r′1(7)={d(6)@z(6)}@{d(6)}=z(6)

Formula 9 for finding this ΔR2(Δr1(0) . . . Δr1(7)) is equivalent to the formula in R1(r1(0) . . . r1(7)) in Formula 3 in which data D0(d0(0) . . . d0(7)) is “00.”

Accordingly, when finding ΔR16(Δr16(0) . . . Δr16(7)) as well, since ΔR16(Δr16(0) . . . Δr16(7)) can be found by finding the case in which all data D0(d0(0) . . . d0(7)) to D15(d15(0) . . . d15(7)) are made “00” in Formula 3, R16(r16(0) . . . r16 (7)) can be found by applying Formula 3 for a case in which data are made “00” successively from ΔR2(Δr2(0) . . . Δr2(7)) to ΔR16(Δr16(0) . . . Δr16(7)).

(2) The Calculation of ΔR2(Δr2(0) . . . Δr2(7))

### Formula 10

Δr2(0)=Δr1(7)

Δr2(1)=Δr1(0)

Δr2(2)=Δr1(1)@ Δr1(7)

Δr2(3)=Δr1(2)@ Δr1(7)

Δr2(4)=Δr1(3)@ Δr1(7)

Δr2(5)=Δr1(4)

Δr2(6)=Δr1(5)

Δr2(7)=Δr1(6)

ΔR1(Δr1(0) . . . Δr1(7)) is shown in Formula 9, resulting in Formula 11.

### Formula 11

Δr2(0)=z(6)

Δr2(1)=z(7)

Δr2(2)=z(0)@z(6)

Δr2(3)=z(1)@z(7)@z(6)

Δr2(4)=z(2)@z(7)@z(6)

Δr2(5)=z(3)@z(7)

Δr2(6)=z(4)

Δr2(7)=z(5)

(3) The Calculation of ΔR3(Δr3(0) . . . Δr3(7))

### Formula 12

Δr3(0)=Δr2(7)

Δr3(1)=Δr2(0)

Δr3(2)=Δr2(1)@Δr2(7)

Δr3(3)=Δr2(2)@Δr2(7)

Δr3(4)=Δr2(3)@Δr2(7)

Δr3(5)=Δr2(4)

Δr3(6)=Δr2(5)

Δr3(7)=Δr2(6)

ΔR2(Δr2(0) . . . Δr2(7)) is shown in Formula 11, resulting in Formula 13.

### Formula 13

Δr3(0)=z(5)

Δr3(1)=z(6)

Δr3(2)=z(7)@z(5)

Δr3(3)=z(0)@z(6)@z(5)

Δr3(4)=z(1)@z(7)@z(6)@z(5)

Δr3(5)=z(2)@z(7)@z(6)

Δr3(6)=z(3)@(7)

Δr3(7)=z(4)

(4) The Calculation of ΔR4(Δr4(0) . . . Δr4(7))

### Formula 14

Δr4(0)=Δr3(7)

Δr4(1)=Δr3(0)

Δr4(2)=Δr3(1)@Δr3(7)

Δr4(3)=Δr3(2)@Δr3(7)

Δr4(4)=Δr3(3)@Δr3(7)

Δr4(5)=Δr3(4)

Δr4(6)=Δr3(5)

Δr4(7)=Δr3(6)

ΔR3(Δr3(0) . . . Δr3(7)) is shown in Formula 13, resulting in Formula 15.

### Formula 15

Δr4(0)=z(4)

Δr4(1)=z(5)

Δr4(2)=z(6)@z(4)

Δr4(3)=z(7)@z(5)@z(4)

Δr4(4)=z(0)@z(6)@z(5)@z(4)

Δr4(5)=z(1)@z(7)@z(6)@z(5)

Δr4(6)=z(2)@z(7)@z(6)

Δr4(7)=z(3)@z(7)

(5) The Calculation of ΔR5(Δr5(0) . . . Δr5(7))

### Formula 16

Δr5(0)=Δr4(7)

Δr5(1)=Δr4(0)

Δr5(2)=Δr4(1)@Δr4(7)

Δr5(3)=Δr4(2)@Δr4(7)

Δr5(4)=Δr4(3)@Δr4(7)

Δr5(5)=Δr4(4)

Δr5(6)=Δr4(5)

Δr5(7)=Δr4(6)

ΔR4(Δr4(0) . . . Δr4(7)) is shown in Formula 15, resulting in Formula 17.

### Formula 17

Δr5(0)=z(3)@z(7)

Δr5(1)=z(4)

Δr5(2)=z(5)@z(3)@z(7)

Δr5(3)=z(6)@z(4)@z(3)@z(7)

Δr5(4)=z(7)@z(5)@z(4)@z(3)@z(7)

Δr5(5)=z(0)@z(6)@z(5)@z(4)

Δr5(6)=z(1)@z(7)@z(6)@z(5)

Δr5(7)=z(2)@z(7)@z(6)

(6) The Calculation of ΔR6(Δr6(0) . . . Δr6(7))

### Formula 18

Δr6(0)=Δr5(7)

Δr6(1)=Δr5(0)

Δr6(2)=Δr5(1)@Δr5(7)

Δr6(3)=Δr5(2)@Δr5(7)

Δr6(4)=Δr5(3)@Δr5(7)

Δr6(5)=Δr5(4)

Δr6(6)=Δr5(5)

Δr6(7)=Δr5(6)

ΔR5(Δr5(0) . . . Δr5(7)) is shown in Formula 17, resulting in Formula 19.

### Formula 19

Δr6(0)=z(2)@z(7)@z(6)

Δr6(1)=z(3)@z(7)

Δr6(2)=z(4)@z(2)@z(7)@z(6)

Δr6(3)=z(5)@z(3)@z(7)@z(2)@z(7)@z(6)

Δr6(4)=z(6)@z(4)@z(3)@z(7)@z(2)@z(7)@z(6)

Δr6(5)=z(7)@z(5)@z(4)@z(3)@z(7)

Δr6(6)=z(0)@z(6)@z(5)@z(4)

Δr6(7)=z(1)@z(7)@z(6)@z(5)

(7) The Calculation of ΔR7(Δr7(0) . . . Δr7(7))

### Formula 20

Δr7(0)=Δr6(7)

Δr7(1)=Δr6(0)

Δr7(2)=Δr6(1)@Δr6(7)

Δr7(3)=Δr6(2)@Δr6(7)

Δr7(4)=Δr6(3)@Δr6(7)

Δr7(5)=Δr6(4)

Δr7(6)=Δr6(5)

Δr7(7)=Δr6(6)

ΔR6(Δr6(0) . . . Δr6(7)) is shown in Formula 19, resulting in Formula 21.

### Formula 21

Δr7(0)=z(1)@z(7)@z(6)@z(5)

Δr7(1)=z(2)@z(7)@z(6)

Δr7(2)=z(3)@z(7)@z(1)@z(7)@z(6)@z(5)

Δr7(3)=z(4)@z(2)@z(7)@z(6)@z(1)@z(7)@z(6)@z(5)

Δr7(4)=z(5)@z(3)@z(7)@z(2)@z(7)@z(6)@z(1)@z(7)@z(6)@z(5)

Δr7(5)=z(6)@z(4)@z(3)@z(7)@z(2)@z(7)@z(6)

Δr7(6)=z(7)@z(5)@z(4)@z(3)@Z (7)

Δr7(7)=z(0)@z(6)@z(5)@z(4)

(8) The Calculation of ΔR8(Δr8(0) . . . Δr8(7))

### Formula 22

Δr8(0)=Δr7(7)

Δr8(1)=Δr7(0)

Δr8(2)=Δr7(1)@Δr7(7)

Δr8(3)=Δr7(2)@Δr7(7)

Δr8(4)=Δr7(3)@Δr7(7)

Δr8(5)=Δr7(4)

Δr8(6)=Δr7(5)

Δr8(7)=Δr7(6)

ΔR7(Δr7(0) . . . Δr7(7)) is shown in Formula 21, resulting in both Formula 23 and Formula 24.

### Formula 23

Δr8(0)=z(0)@z(6)@z(5)@z(4)

Δr8(1)=z(1)@z(7)@z(6)@z(5)

Δr8(2)=z(2)@z(7)@z(6)@z(0)@z(6)@z(5)@z(4)

Δr8(3)=z(3)@z(7)@z(1)@z(7)@z(6)@z(5)@z(0)@z(6)@z(5)@z(4)

Δr8(4)=z(4)@(2)@z(7)@z(6)@z(1)@z(7)@z(6)@z(5)@z(0)@z(6)@z(5)@z(4)

Δr8(5)=z(5)@z(3)@z(7)@z(2)@z(7) z(6)@z(1)@z(7)@z(6)@z(5)

Δr8(6)=z(6)@z(4)@z(3)@z(7)@z(2)@z(7)@z(6)

Δr8(7)=z(7)@z(5)@z(4)@z(3)@z(7)

### Formula 24

Δr8(0)=z(0)@z(6)@z(5)@z(4)=z(0)@z(4)@z(5)@z(6)

Δr8(1)=z(1)@z(7)@z(6)@z(5)=z(1)@z(4)@z(5)@z(6)

Δr8(2)=z(2)@z(7)@z(0)@z(6)@z(5)@z(4)=z(0)@z(2)@z(4)@z(5)@z(7)

Δr8(3)=z(3)@z(1)@z(0)@z(4)=z(0)@z(1)@z(3)@z(4)

Δr8(4)=z(2)@z(1)@z(0)@z(6)=z(0)@z(1)@z(2)@z(6)

Δr8(5)=z(3)@z(2)@z(1)@z(7)=z(1)@z(2)@z(3)@z(7)

Δr8(6)=z(4)@z(3)@z(2)=z(2)@z(3)@z(4)

Δr8(7)=z(5)@z(4)@z(3)=z(3)@z(4)@z(5)

(9) The Calculation of ΔR9(Δr9(0) . . . Δr9(7))

### Formula 25

Δr9(0)=Δr8(7)

Δr9(1)=Δr8(0)

Δr9(2)=Δr8(1)@Δr8(7)

Δr9(3)=Δr8(2)@Δr8(7)

Δr9(4)=Δr8(3)@Δr8(7)

Δr9(5)=Δr8(4)

Δr9(6)=Δr8(5)

Δr9(7)=Δr8(6)

ΔR8(Δr8(0) . . . Δr8(7)) is shown in Formula 24, resulting in Formula 26.

### Formula 26

Δr9 (0)=z(3)@z(4)@z(5)

Δr9 (1)=z(0)@z(4)@z(5)@z(6)

Δr9 (2)=z(1)@z(5)@z(6)@z(7)@z(3)@z(4)@z(5)

Δr9 (3)=z(0)@z(2)@z(4)@z(5)@z(7)@z(3)@z(4)@z(5)

Δr9 (4)=z(0)@z(1)@z(3)@z(4)@z(3)@z(4)@z(5)

Δr9 (5)=z(0)@(1)@z(2)@z(6)

Δr9 (6)=z(1)@z(2)@z(3)@z(7)

Δr9 (7)=z(2)@z(3)@z(4)

(10) The Calculation of ΔR10(Δr10(0) . . . Δr10(7))

### Formula 27

Δr10(0)=Δr9(7)

Δr10(1)=Δr9(0)

Δr10(2)=Δr9(1)@Δr9(7)

Δr10(3)=Δr9(2)@Δr9(7)

Δr10(4)=Δr9(3)@Δr9(7)

Δr10(5)=Δr9(4)

Δr10(6)=Δr9(5)

Δr10(7)=Δr9(6)

ΔR9(Δr9(0) . . . Δr9(7)) is shown in Formula 26, resulting in both Formula 28 and Formula 29.

### Formula 28

Δr10(0)=z(2)@z(3)@z(4)

Δr10(1)=z(3)@z(4)@z(5)

Δr10(2)=z(0)@z(4)@z(5)@z(6)@z(2)@z(3)@z(4)

Δr10(3)=z(1)@z(5)@z(6)@z(7)@z(3)@z(4)@z(5)@z(2)@z(3)@z(4)

Δr10(4)=z(0)@z(2)@z(4)@z(5)@z(7)@z(3)@z(4)@z(5)@z(2)@z(3)@z(4)

Δr10(5)=z(0)@z(1)@z(3)@z(4)@z(3)@z(4)@z(5)

Δr10(6)=z(0)@z(1)@z(2)@z(6)

Δr10(7)=z(1)@z(2)@z(3)@z(7)

### Formula 29

Δr10(0)=z(2)@z(3)@z(4)

Δr10(1)=z(3)@z(4)z(5)

Δr10(2)=z(0)@z(2)@z(3)@z(5)@z(6)

Δr10(3)=z(1)@z(2)@z(6)@z(7)

Δr10(4)=z(0)@z(4)@z(7)

Δr10(5)=z(0)@z(1)@z(5)

Δr10(6)=z(0)@z(1)@z(2)@z(6)

Δr10(7)=z(1)@z(2)@z(3)@z(7)

(11) The Calculation of ΔR11(Δr11(0) . . . Δr11(7))

### Formula 30

Δr11(0)=Δr10(7)

Δr11(1)=Δr10(0)

Δr11(2)=Δr10(i)@Δr10(7)

Δr11(3)=Δr10(2)@Δr10(7)

Δr11(4)=Δr10(3)@Δr10(7)

Δr11(5)=Δr10(4)

Δr11(6)=Δr10(5)

Δr11(7)=Δr10(6)

ΔR10(Δr10(0) . . . Δr10(7)) is shown in Formula 29, resulting in Formula 31.

### Formula 31

Δr11(0)=z(1)@z(2)@z(3)@z(7)

Δr11(1)=z(2)@z(3)@z(4)

Δr11(2)=z(3)@z(4)@z(5)@z(1)@z(2)@z(3)@z(7)

Δr11(3)=z(0)@z(2)@z(3)@z(5)@z(6)@z(1)@z(2)@z(3)@z(7)

Δr11(4)=z(1)@z(2)@z(6)@z(7)@z(1)@z(2)@z(3)@z(7)

Δr11(5)=z(0)@z(4)@z(7)

Δr11(6)=z(0)@z(1)@z(5)

Δr11(7)=z(0)@z(1)@z(2)@z(6)

(12) The Calculation of ΔR12(Δr12(0) . . . Δr12(7))

### Formula 32

Δr12(0)=Δr11(7)

Δr12(1)=Δr11(0)

Δr12(2)=Δr11(l)@Δr11(7)

Δr12(3)=Δr11(2)@Δr11(7)

Δr12(4)=Δr11(3)@Δr11(7)

Δr12(5)=Δr11(4)

Δr12(6)=Δr11(5)

Δr12(7)=Δr11(6)

A ΔR11(Δr11(0) . . . Δr11(7)) is shown in Formula 31, resulting in both Formula 33 and Formula 34.

### Formula 33

Δr12(0)=z(0)@z(1)@z(2)@z(6)

Δr12(1)=z(1)@z(2)@z(3)@z(7)

Δr12(2)=z(2)@z(3)@z(4)@z(0)@z(1)@z(2)@z(6)

Δr12(3)=z(3)@z(4)@z(5)@z(1)@z(2)@z(3)@z(7)@z(0)@z(1)@z(2)@z(6)

Δr12(4)=z(0)@z(2)@z(3)@z(5)@z(6) z(1)@z(2)@z(3)@z(7)@(0)@z(1)@z(2)@z(6)

Δr12(5)=z(1)@z(2)@z(6)@z(7)@z(1)@z(2)@z(3)@z(7)

Δr12(6)=z(0)@z(4)@z(7)

Δr12(7)=z(0)@z(1)@z(5)

### Formula 34

Δr12(0)=z(0)@z(1)@z(2)@z(6)

Δr12(1)=z(1)@z(2)@z(3)@z(7)

Δr12(2)=z(0)@z(1)@z(3)@z(4)@z(6)

Δr12(3)=z(0)z(4)@z(5)@z(6)@z(7)

Δr12(4)=z(2)@z(5)@z(7)

Δr12(5)=z(3)@z(6)

Δr12(6)=(0)@z(4)@z(7)

Δr12(7)=z(0)@z(1)@z(5)

(13) The Calculation of ΔR13(Δr13(0) . . . Δr13(7))

### Formula 35

Δr13(0)=Δr12(7)

Δr13(1)=Δr12(0)

Δr13(2)=Δr12(1)@Δr12(7)

Δr13(3)=Δr12(2)@Δr12(7)

Δr13(4)=Δr12(3)@Δr12(7)

Δr13(5)=Δr12(4)

Δr13(6)=Δr12(5)

Δr13(7)=Δr12(6)

ΔR12(Δr12(0) . . . Δr12(7)) is shown in Formula 34, resulting in Formula 36.

### Formula 36

Δr13(0)=z(0)@z(1)@z(5)

Δr13(1)=z(0)@z(1)@z(2)@z(6)

Δr13(2)=z(1)@z(2)@z(3)@z(7)@z(0)@z(1)@z(5)

Δr13(3)=z(0)@z(1)@z(3)@z(4)@z(6)@z(0)@z(1)@z(5)

Δr13(4)=z(0)@z(4)@z(5)@z(6)@z(7)@z(0)@z(1)@z(5)

Δr13(5)=z(2)@z(5)@z(7)

Δr13(6)=z(3)@z(6)

Δr13(7)=z(0)@z(4)@z(7)

(14) The Calculation of ΔR14(Δr14(0) . . . Δr14(7))

### Formula 37

Δr14(0)=Δr13(7)

Δr14(1)=Δr13(0)

Δr14(2)=Δr13(1)@Δr13(7)

Δr14(3)=Δr13(2)@Δr13(7)

Δr14(4)=Δr13(3)@Δr13(7)

Δr14(5)=Δr13(4)

Δr14(6)=Δr13(5)

Δr14(7)=Δr13(6)

ΔR13(Δr13(0) . . . Δr13(7)) is shown in Formula 36, resulting in both Formula 38 and Formula 39.

### Formula 38

Δr14(0)=z(0)@z(4)@z(7)

Δr14(1)=z(0)@z(1)@z(5)

Δr14(2)=z(0)@z(1)@z(2)@z(6)@z(0)@z(4)@z(7)

Δr14(3)=z(1)@z(2)@z(3)@z(7)@z(0)@z(1)@z(5)@z(0)@z(4)@z(7)

Δr14(4)=z(0)@z(1)@z(3)@z(4)@z(6)@z(0)@z(1)@z(5)@z(0)@z(4)@z(7)

Δr14(5)=z(0)@z(4)@z(5)@z(6)@z(7)@z(0)@z(1)@z(5)

Δr14(6)=z(2)@z(5)@z(7)

Δr14(7)=z(3)@z(6)

### Formula 39

Δr14(0)=z(0)@z(4)@z(7)

Δr14(1)=z(0)@z(1)@z(5)

Δr14(2)=z(1)@z(2)@z(4)@z(6)@z(7)

Δr14(3)=z(2)@z(3)@z(4)@z(5)

Δr14(4)=z(0)@z(3)@z(5)@z(6)@z(7)

Δr14(5)=z(1)@z(4)@z(6)@z(7)

Δr14(6)=z(2)@z(5)@z(7)

Δr14(7)=z(3)@z(6)

(15) The Calculation of ΔR15(Δr15(0) . . . Δr15(7))

### Formula 40

Δr15(0)=Δr14(7)

Δr15(1)=Δr14(0)

Δr15(2)=Δr14(1)@Δr14(7)

Δr15(3)=Δr14(2)@Δr14(7)

Δr15(4)=Δr14(3)@Δr14(7)

Δr15(5)=Δr14(4)

Δr15(6)=Δr14(5)

Δr15(7)=Δr14(6)

ΔR14(Δr14(0) . . . Δr14(7)) is shown in Formula 39, resulting in Formula 41.

### Formula 41

Δ15(0)=z(3)@z(6)

Δ15(1)=z(0)@z(4)@z(7)

Δ15(2)=z(0)@z(1)@z(5)@z(3)@z(6)

Δ15(3)=z(1)@z(2)@z(4)@z(6)@z(7)@z(3)@z(6)

Δ15(4)=z(2)@z(3)@z(4)@z(5)@z(3)@z(6)

Δ15(5)=z(0)@z(3)@z(5)@z(6)@z(7)

Δ15(6)=z(1)@z(4)@z(6)@z(7)

Δ15(7)=z(2)@z(5)@z(7)

(16) The Calculation of ΔR16(Δr16(0) . . . Δr16(7))

### Formula 42

Δr16(0)=Δr15 (7)

Δr16(1)=Δr15(0)

Δr16(2)=Δr15(1)@Δ15(7)

Δr16(3)=Δr15(2)@Δ15(7)

Δr16(4)=Δr15(3)@Δ15(7)

Δr16(5)=Δr15(4)

Δr16(6)=Δr15(5)

Δr16(7)=Δr15(6)

ΔR15(Δr15(0) . . . Δr15(7)) is shown in Formula 41, resulting in both Formula 43 and Formula 44.

### Formula 43

Δr16(0)=z(2)@z(5)@z(7)

Δr16(1)=z(3)@z(6)

Δr16(2)=z(0)@z(4)@z(7)@z(2)@z(5)@z(7)

Δr16(3)=z(0)@z(1)@z(5)@z(3)@z(6)@z(2)@z(5)@z(7)

Δr16(4)=z(1)@z(2)@z(4)@z(6)@z(7)@z(3)@z(6)@z(2)@z(5)@z(7)

Δr16(5)=z(2)@z(3)@z(4)@z(5)@z(3)@z(6)

Δr16(6)=z(0)@z(3)@z(5)@z(6)@z(7)

Δr16(7)=z(1)@z(4)@z(6)@z(7)

### Formula 44

Δr16(0)=z(2)@z(5)@z(7)

Δr16(1)=z(3)@z(6)

Δr16(2)=z(0)@z(2)@z(4)@z(5)

Δr16(3)=z(0)@z(1)@z(2)@z(3)@z(6)@z(7)

Δr16(4)=z(1)@z(3)@z(4)@z(5)

Δr16(5)=z(2)@z(4)@z(5)@z(6)

Δr16(6)=z(0)@z(3)@z(5)@z(6)@z(7)

Δr16(7)=z(1)@z(4)@z(6)@z(7)

By means of the above calculations, ΔR16(Δr16(0) . . . Δr16(7)) is found by Formula 44, and the formula ΔR16(r16(0) . . . r16(7))=R′16(r′16(0) . . . r′16(7))@ΔR16(Δr16(0) . . . Δr16(7)) can be generated.

Here, R′16(r′16(0) . . . r′16(7)) is shown in Formula 6 and is the block CRC code for sending a 16-byte data block when initial values (z(0) . . . z′(7)) are made “00”; and ΔR16(Δr16(0) . . . Δr16(7)) is shown in Formula 44 and is the amount of displacement of Z(z(0) . . . z(7)) when sending a 16-byte data block when initial values are made Z(z(0) . . . z(7)).

FIG. 10 illustrates this point.

If the formula R16(r16(0) . . . r16(7))=R′16(r′16(0) . . . r′16(7))@ΔR16(Δr16(0) . . . Δr(7)) is defined as a “BCRC operation,” the process shown in FIG. 11 can be realized.

At this time, the block CRC operation formula for finding R16(r16(0) . . . r16(7)) is Formula 45.

### Formula 45

Δr16(0)=r′16(0)@z(2)@z(5)@z(7)

Δr16(1)=r′16(1)@z(3)@z(6)

Δr16(2)=r′16(2)@z(0)@z(2)@z(4)@z(7)

Δr16(3)=r′16(3)@z(0)@z(1)@z(2)@z(3)@z(4)@z(5)@z(7)

Δr16(4)=r′16(4)@z(1)@z(3)@z(4)@z(7)

Δr16(5)=r′16(5)@z(2)@z(4)@z(5)@z(6)

Δr16(6)=r′16(6)@z(0)@z(3)@z(5)@z(6)@z(7)

Δr16(7)=r′16(7)@z(1)@z(4)@z(6)@z(7)

Accordingly, the circuit of FIG. 11 is connected in data block units to constitute a circuit for finding the final CRC operation result, producing a circuit such as shown in FIG. 12.

Here, CRC operation result R512(r512(0) . . . r512(7)) is the CRC operation result when data from D0(d0(0) . . . d0(7)) to D512(d512(0) . . . d512(7)) are transferred, by the way applying the CRC codes contained in sector data to this as data D513(d513(0) . . . d513(7)) indicates that normal transfer has been achieved if R513(r513(0) . . . r513(7)) becoms “00.”

In addition, in a “BCRC operation” for generating R513(r513(0) . . . r513(7)) from the final R512(r512(0) . . . r512(7)) and R′513(r′513(0) . . . r′513(7)), the data that are transferred are the single byte D513(d513(0) . . . r513(7)), and since this differs from the “BCRC operation” in Formula 22 when transferring 16 bytes, an operation when transferring one byte is necessary. Since this results in the amount of displacement already defined by Formula 9, Formula 46 is used.

### Formula 46

Δr513(0)=r′513(0)@r512(7)

Δr513(1)=r′513(1)@r512(0)

Δr513(2)=r′513(2)@r512(1)@r512(7)

Δr513(3)=r′513(3)@r512(2)@r512(7)

Δr513(4)=r′513(4)@r512(3)@r512(7)

Δr513(5)=r′513(5)@r512(4)

Δr513(6)=r′513(6)@r512(5)

Δr513(7)=r′513(7)@r512(6)

In the above-described embodiment, although an example was described that is used in, for example, a disk array system, in which sector data and CRC code from host device 1 are combined to make 520 bytes, and initial values Z(z(0) . . . z(7)) of the CRC codes are set to “00” when memory device 5 accesses one data block (16-byte unit) and generates block CRC codes, these initial values can be any value in the present invention, and no limit is placed on the scope of application of the present invention.

As the first effect of the present invention, a device that is a data transfer source is able to detect how data were transferred to the ultimate memory device, whereby alteration of data midway on the path of data transfer can be reliably detected and the integrity of the data can be increased.

As the second effect of the present invention, the checking logic of CRC codes exists on the host adapter side, which is the data transfer source, whereby increase in the hardware on the memory adapter side can be avoided and circuit complexity can be prevented even in a configuration that includes a plurality of host devices.

As a third effect of the present invention, the invention is not a data transfer system in which CRC codes are always added to data block units, and the invention can therefore be employed without causing any reduction of the transmission rate of the bus; and further, the circuits of the invention other than the circuit portion in which block CRC codes are returned are identical to the circuits of a conventional data transfer system, and the invention can therefore be easily applied to raise the integrity of data without necessitating a drastic modification of circuits.

While preferred embodiments of the present invention have been described using specific terms, such description is for illustrative purposes only, and it is to be understood that changes and variations may be made without departing from the spirit or scope of the following claims.

What is claimed is:

1. A data transfer system provided with a host adapter that deblocks sector data for which a write request has been issued from a host device and issues a write request to store the deblocked sector data as a plurality of data blocks, and a memory adapter that memory-writes said data blocks to a memory device; wherein
said memory adapter further comprises means for generating a particular determined code for each of the data blocks and returning the generated code to said host adapter as a write reply; and
said host adapter further comprises means for reconstructing CRC (Cyclic Redundancy Check) code of the sector code from said particular determined returned code as a write reply from said memory adapter, verifying the reconstructed CRC code of sector data coincides with the CRC code of the original sector data, and reporting the presence or absence of errors to said host device.

2. A data transfer system according to claim 1, wherein said particular determined code is block CRC code that is computed for predetermined portions of said data blocks in a state having particular initial,values.

3. A data transfer system according to claim 2, wherein, when generating said block CRC code, zero “0” is applied for said initial values.

4. A data transfer system according to claim 1, further comprising a crossbar circuit between said host adapter and said memory adapter for interconnecting the data transfer.

5. A data transfer system according to claim 2, further comprising a crossbar circuit between said host adapter and said memory adapter for interconnecting the data transfer.

6. A data transfer system according to claim 3, further comprising a crossbar circuit between said host adapter and said memory adapter for interconnecting the data transfer.

7. A data transfer system provided with a host adapter that deblocks sector data for which a write request has been issued from a host device and issues a write request to store the deblocked sector data as a plurality of data blocks, a memory adapter that memory-writes said data blocks to a memory device and a bus that interconnects said host adapter and said memory adapter; wherein
said memory adapter further comprises means for generating a particular determined code for each of the data blocks and returning the generated codes to said host adapter as a write reply
to said host adapter by way of said bus; and
said host adapter further comprises means for reconstructing CRC (Cyclic Redundancy Check) code of the sector code from said particular determined returned code as a write reply from said memory adapter by way of said bus, verifying the reconstructed CRC code of sector data coincides the CRC code of the original sector data, and reporting the presence or absence of errors to said host device

8. A data transfer system provided with a plurality of host adapters that each of them deblocks sector data for which a write request has been issued from a host device and issues a write request to store the deblocked sector data as a plurality of data blocks, a plurality of memory adapters that each of them memory-writes to one of a plurality of memory devices the data blocks for which said write request has been issued, and a bus that interconnects said host adapters and said memory adapters: wherein
each of memory adapters further comprises means, when performing a memory-writing to said memory device of data blocks for which a write request has been issued, generating block CRC code for the data blocks and returning this code as a write reply to said host adapter by way of said bus; and each host adapter further comprises means for reconstructing CRC code of sector data from the block CRC code that has been returned as a write reply from said memory adapter by way of said bus, verifying that the reconstructed code coincides the CRC code of the original sector data, and reporting the presence or absence of errors to said host device.

9. A data transfer system according to claim 7, wherein said host adapter comprises:
a data buffer for buffering said sector data;
a block CRC code to CRC code conversion circuit for reconstructing CRC code of complete sector data from block CRC codes that have been returned as said write reply; and
a CRC code check circuit for verifying that the reconstructed CRC code coincides with the CRC code of the original sector data.

10. A data transfer system according to claim 8, wherein said host adapter comprises:
a data buffer for buffering said sector data;
a block CRC code to CRC code conversion circuit for reconstructing CRC code of complete sector data from block CRC codes that have been returned as said write reply; and
a CRC code check circuit for verifying that the reconstructed CRC code coincides with the CRC code of the original sector data.

11. A data transfer system according to claim 9, wherein a plurality of said CRC code check circuits are provided in correspondence with channels, the channel of a data transfer source is specified by a channel number, and verification of reconstructed CRC code is realized using a CRC code check circuit that corresponds to that channel.

12. A data transfer system according to claim 10, wherein a plurality of said CRC code check circuits are provided in correspondence with channels, the channel of a data transfer source is specified by a channel number, and verification of reconstructed CRC code is realized using a CRC code check circuit that corresponds to that channel.

13. A data transfer system according to claim 7, wherein said memory adapter comprises:
a data buffer for buffering data blocks for which a write request has been issued from said host adapter; and
a block CRC code generation circuit for generating block CRC code for data blocks that have been memory-written from said data buffer to said memory device.

14. A data transfer system according to claim 8, wherein said memory adapter comprises:
a data buffer for buffering data blocks for which a write request has been issued from said host adapter; and
a block CRC code generation circuit for generating block CRC code for data blocks that have been memory-written from said data buffer to said memory device.

15. A data transfer system according to claim 13, wherein said block CRC code generation circuit sets initial values to zero when generating said block CRC code.

16. A data transfer system according to claim 14, wherein said block CRC code generation circuit sets initial values to zero when generating said block, CRC code.

17. A data transfer system provided with a host adapter that deblocks sector data for which a write request has been issued from a host device and that issues a write request as a plurality of data blocks, a memory adapter that memory-writes to a memory device data blocks for which said write request has been issued, and a crossbar circuit that interconnects said host adapter and said memory adapter; wherein
said memory adapter further comrises means, when performing a memory write to said memory device of data blocks for which a write request has been issued from said host adapter by way of said crossbar circuit, generating block CRC code from the data blocks and returns as a write reply to said host adapter by way of said crossbar circuit; and
said host adapter further comprises means for reconstructing CRC code of complete sector data from said block CRC code that has been returned as a write reply from said memory adapter by way of said crossbar circuit, verifying that the reconstructed CRC code coincides with the CRC code of the original sector data, and reporting the presence or absence of errors to said host device.

18. A data transfer system according to claim 17, wherein said host adapter comprises:
a data buffer for buffering said sector data;
a block CRC code to CRC code conversion circuit for reconstructing CRC code of complete sector data from block CRC codes that have been returned as a write reply from said memory adapter;
a CRC code check circuit for verifying that CRC code that has been reconstructed by said block CRC code to CRC code conversion circuit is CRC code of the original sector data;
a host control circuit for controlling said host device; and
a bus interface for controlling the interface with said crossbar circuit.

19. A data transfer system according to claim 18, wherein a plurality of said CRC code check circuits are provided in correspondence with channels, the channel of a data transfer source is specified by a channel number, and verification of reconstructed CRC code is realized using the CRC code check circuit that corresponds to that channel.

20. A data transfer system according to claim 17, wherein said memory adapter comprises:
a data buffer for buffering data blocks for which a write request has been issued from said host adapter;
a block CRC code generation circuit for generating block CRC code for data blocks that have been memory-written to said memory device from said data buffer; and
a bus interface for controlling the interface with said crossbar circuit.

21. A data transfer system according to claim 20, wherein said block CRC code generation circuit sets initial values to zero when generating said block CRC code.

22. A data transfer system according to claim 17, wherein said crossbar circuit includes:
a first bus interface for controlling the interface with said host adapter;
a second bus interface for controlling the interface with said memory adapter; and
a plurality of data buffers provided between said first bus interface and said second bus interface.
